(19) United States
(12) Patent Application Publication
(10) Pub. No.: US 2013/0025664 A1
(43) Pub. Date: Jan. 31, 2013

(54) SOLAR CELL ELECTRODE, AND METHOD FOR MANUFACTURING THE SAME, AND PASTE FOR THE SOLAR CELL ELECTRODE

(71) Applicants: Hiroki Kojo, Tochigi (JP); Masakatsu Kuroki, Kanagawa (JP); Hisashi Matsuno, Tokyo (JP)

(72) Inventors: Hiroki Kojo, Tochigi (JP); Masakatsu Kuroki, Kanagawa (JP); Hisashi Matsuno, Tokyo (JP)

(73) Assignee: E.I. DU PONT DE NEMOURS AND COMPANY, Wilmington, DE (US)

(21) Appl. No.: 13/363,431

(22) Filed: Feb. 1, 2012

(30) Foreign Application Priority Data
Feb. 4, 2011 (JP) 2011-23052

(51) Int. Cl. H01B 1/02; H01L 31/0224; H01L 31/18

(52) U.S. Cl. 136/256; 438/98; 252/512; 257/E31.124

(57) ABSTRACT

The invention relates to a paste for forming a solar cell electrode, comprising electrically conductive metal particles, glass frit, a cross-linkable agent, a photo polymerization initiator and organic solvent, wherein the content of the cross-linkable agent is 1.0 to 20.0 wt %, the content of the photo polymerization initiator is 0.2 to 15.0 wt %, the content of the organic solvent is greater than 1.0 wt %, based on the total weight of the paste, and wherein over 90 wt % of the organic solvent based on the total weight of the organic solvent has a boiling point at 85° C. or higher.

### FIELD OF THE INVENTION

The present invention is directed to a photo-curable conductive paste used in fabricating electrodes for solar cells. The present invention also relates to a method for fabricating solar cell electrodes by using the paste. The present invention further includes a solar cell electrode made from the photo-curable conductive paste.

### TECHNICAL BACKGROUND OF THE INVENTION

A solar cell structure with a p-type base has a negative electrode that is typically on the front-side or sun side of the cell and a positive electrode on the backside. When solar radiation of an appropriate wavelength falls on a p-n junction of a semiconductor body, hole-electron pairs are generated in that body. Holes and electrons move across the junction in opposite directions and thereby give rise to flow of an electric current through the contacts disposed on the front-side and backside, which is capable of delivering power to an external circuit. The contact on the front side is generally made in the form of a grid comprising widely-spaced thin metal lines, or fingers, that supply current to a larger bus bar. The back contact is generally not constrained to be formed in multiple thin metal lines, since it does not prevent incident light from striking solar cell.

In order to increase the power generation characteristics of the solar cell the characteristic of the conversion efficiency EFF (%) is particularly important factor among the factors determining the efficiency of a solar cell. In order to increase the conversion efficiency, suitable electrode (grid) design is such as to attain high conduciveness, to cause electrons to move efficiently and to not decrease the area of the front surface on which solar radiation is incident. As a result; the power generation efficiency is increased. In order to achieve this objective, a variety of solar cell manufacturing techniques for fabricating electrodes having a high-aspect ratio for a solar cell by applying a conductive paste having a predetermined viscosity range (for example, by screen-printing) and for attaining superior conversion efficiency EFF (%) have been proposed.

A process for forming solar cell electrodes having a high aspect ratio, which attains superior conversion efficiency EFF (%) by screen-printing a conductive paste containing carbon fibers have been disclosed in US-2010-0294353 A1. The process described therein involves the screen printing and there are limitations to the aspect ratio of the formed electrode by screen printing. Moreover, the aspect ratio of the formed electrode is decreased after the firing process.

Japanese published patent application No. 2011-5404 (Kokai) describes a printing method and a device for forming solar cell electrodes by applying conductive paste through the discharge slot of a nozzle dispenser onto the wafer. In this application, to get high aspect ratio electrodes, means for controlling the viscosity of the conductive paste after being applied on the wafer is described as one of essential parts of the invention. However, having such means in the device or using such means in the process is actually a very impractical and inefficient way to get high aspect ratio electrodes. Despite the numerous techniques utilized, a need still exists for electrodes for solar cells having superior conversion efficiency EFF (%), while increasing the requirement for reducing damage to global environment and cost reduction.

### SUMMARY OF THE INVENTION

In one aspect, the present invention relates to a photo-curable conductive paste for making a solar cell electrode comprising:

electrically conductive metal particles;

glass frit;

a cross-linkable agent;

a photo polymerization initiator; and

organic solvent, wherein the content of the cross-linkable agent is 1.0 to 20.0 wt %, the content of the photo polymerization initiator is 0.2 to 15.0 wt %, and the content of the organic solvent is over 1.0 wt %, based on the weight of the paste, and wherein over 90 wt % of the organic solvent, based on the total weight of the organic solvent, has a boiling point at 85° C. or higher.

In another aspect of the present invention, a method for producing a solar cell electrode by using a dispenser, comprising the steps:

(a) providing a paste for a solar cell electrode comprising:
electrically conductive metal particles:
glass frit;
a cross-linkable agent;
a photo polymerization initiator; and
organic solvent, wherein the content of the cross-linkable agent is 1.0 to 20.0 wt %, the content of the photo polymerization initiaor is 0.2 to 15.0 wt %, and the content of the organic solvent is over 1.0 wt %, based on the weight of the paste, and wherein over 90 wt % of the organic solvent, based on total weight of the organic solvent, has a boiling point at 85° C. or higher:

(b) discharging the paste onto the surface of a wafer through a discharge slot of a nozzle unit of a dispenser while moving the nozzle unit in a direction parallel to the surface of the wafer to thereby form an uncured electrode pattern on the surface of the wafer; and

(c) curing the uncured electrode pattern by exposing the uncured electrode pattern to UV light, after or concurrently with step (b) to form the electrode pattern on the wafer.

Another aspect of the present invention provides a solar cell electrode with an aspect ratio which is in the range of 0.3 to 3.0. formed by the above process,

### DETAILED DESCRIPTION OF THE INVENTION

Photo-Curable Conductive Paste Used in the Manufacture of an Electrode for Solar Cell

### Electrically Conductive Metal Particles

In one embodiment, the electrically conductive metal particles used in the invention may be metal particles or metal alloy particles having electrical conductivity of not less than 1.00×10⁷S/m (siemens per meter) at about 20° C. Examples of such metal particles include iron (Fe; 1.00×10⁷S/m), aluminium (Al; 3.64×10⁷ S/m), nickel (Ni; 1.45×10⁷S/m), copper (Cu; 5.81×10⁷S/m), silver (Ag; 6.17×10⁷S/m), gold (Au; 4.17×10⁷S/m), molybdenum (Mo; 2.10×10⁷S/m), magnesium (Mg; 2.30×10⁷S/m), tungsten (W; 1.82×10⁷S/m), cobalt (Co; 1.46×10⁷S/m) and zinc (Zn; 1.64×10⁷S/m). The metal particles can be used alone or in combination with other metal particles. In one embodiment the metal particles used in the photo-curable conductive paste have an electrical conductivity of not less than 3.00×10⁷S/m (siemens per meter) at about 20° C. and such metal particles may be metal powders or metal alloy powders. It is understood that the use of conductive powders having higher electrical conductivity increases the conversion efficiency of solar cells.

In an embodiment The metal powders are selected from the group comprising aluminum, copper, silver, gold, and combinations thereof. The metal powder is silver in another embodiment. Silver is commonly available and relatively inexpensive. In the event that a process for fabricating an electrode includes a firing, it is possible to fire silver metal under an oxygen-containing atmosphere, such as air, since silver is hardly susceptible to oxidation. The metal particles may be in the shape of flakes, spheres. In the present invention, metal particles having the same shape or different shapes may be used as a mixture. In an embodiment, metal particles in the shape of spheres are used when the paste is being used with a nozzle dispenser to provide the flowability and appropriate viscosity of the paste dispensed from the nozzle. The particle diameter (d₅₀) is within the range of 0.1 μm to 5.0 μm in an embodiment and 0.1 μm to 3.0 μm in another embodiment so as to discharge the paste in a predetermined amount from the pressurized nozzle. Normally, the silver has a high purity (greater than 99%). However, substances of lower purity can be used depending on the electrical requirements of the electrode pattern. Although there are no particular limitations on the silver content provided it is an amount that allows the object of the present invention to be achieved, the metal particle content is 40% to 95% in an embodiment and 70% to 90% in another embodiment, by weight based on the weight of the paste.

### Glass Frits

There are no particular limitations on glass frit. Any glass composition suitable for making a conductive paste for electronic applications is suitable for use with the present invention. For example, lead borosilicate glass may be used. Lead borosilicate glass is a superior material in the present invention from the standpoint of both the range of the softening point and glass adhesion. In addition, lead-free glass such as a bismuth silicate lead-free glass can also be used.

When the conductive paste of the present invention is used for the present inventive method for fabricating solar cell electrodes, the softening point of the glass is in the range of 300° C.-600° C. in an embodiment, in the range of 320° C.-520° C. in another embodiment and firing is carried out at a temperature of between 600° C. and 900° C. The fired electrode reacts with and penetrates the insulating film, forming electrical contact with the silicon wafer. The glass softens sufficiently to proceed with firing properly at the firing temperature, so the softening point is >300° C. in an embodiment, >320° C. in another embodiment. On the other hand, from the viewpoint of melting flowability, adhesion strength and liquid-phase firing, the softening point is <600° C. in an embodiment, <520° C. in another embodiment. Although there are no particular limitations on the content of the inorganic binder in the form of the glass frit provided it is an amount that allows the object of the present invention to be achieved, it is 0.5% to 15.0% by weight in an embodiment and 1.0% to 10.0% in another embodiment by weight based on the weight of the paste. If the amount of the inorganic binder is less than 0.5% by weight, adhesive strength may become inadequate. If the amount of the inorganic binder exceeds 15.0% by weight, problems may be caused in the subsequent soldering step due to floating glass. In addition, the resistance value as a conductor also increases.

### Photo Polymerization Initiator

The photo-curable conductive pastes of the present invention contain a photo polymerization initiator in the form of a radical photo polymerization initiator and a cationic photo polymerization initiator. The photo polymerization initiator is thermally inactive at 185° C. or lower in an embodiment, but it generates a free radical or acid when it is exposed to light rays. When the photocurable monomer component used in the present invention contains polymerizable ethylenically unsaturated compound, the radical photo polymerization initiator is used. When the photocurable monomer component used in the present invention contains cationic polymerizable monomer, the cationic photo polymerization initiator is used.

The photo polymerization initiator may be used singly or two or more kinds may be used in combination.

The content of the photo polymerization initiator is in the range of 0.2-15.0 wt % in an embodiment, 0.2-10.0 wt % in another embodiment, and 1.0-5.0 wt % in another embodiment, based on the total amount of the photocurable conductive paste. From the viewpoint of appropriate photo-curability, the content of the photo polymerization initiator is greater than 0.2 wt % in an embodiment, and greater than 1.0 wt % in another embodiment, based on the total amount of the photocurable conductive paste. From the viewpoint of resistance and solubility, the content of the photo polymerization initiator is less than 15.0 wt % in an embodiment, 10 wt % in another embodiment, and 5 wt % in another embodiment, based on the total amount of the photocurable conductive paste.

### (1) Radical Photo Polymerization Initiator

The radical photo polymerization initiator is used for photo-polymerizing the radical polymerization-type monomer and it generates a free radical when it is exposed to light rays. The radical photo polymerization initiator is not particularly limited, but well known radical photo polymerization initiators can be employed. Examples of the photo polymerization initiator include compounds having two intramolecular rings in a conjugated carbon ring. Practical examples include: 9,10-anthraquinone, 2-methylanthraquinone, 2-ethylanthraquinone, 2-t-butylanthraquinone, octamethylanthraquinone, 1,4-naphtoquinone, 9,10-phenanthrenequinone, benzo[a]anthracene-7,12 dione, 2,3-naphtacene-5,12-dione, 2-methyl-1,4-naphtoquinone, 1,4-dimethylanthraquinone, 2,3-dimethylanthraquinone, 2-phenylanthraquinone, 2,3-diphenylanthraquinone, retenequinone, 7,8,9,10-tetrahydronaphtacene-5,12-dione and 1,2,3,4-tetrahydrobenzo[a]anthracene-7,12-dione.

Other compounds that may be used include those given in U.S. Pat. Nos. 2,850,445, 2,875,047, 3,074,974, 3,097,097, 3,145,104, 3,427,161, 3,479,185, 3,549,367, and 4,162,162.

Other examples include: Ethyl-4-(dimethylamino)-benzoate, 2,4-Diethylthioxanthone, 2-Methyl-1[4-(methylthio)-phenyl]-2-morpholinopropnane-1-one, 2-benzil-2-dimethylamino-1-(4-morpholinophenyl)-butanone-1,2(dimethylamino)-2-[(4-methylphenyl)methyl]-1-[4-(4-phenylthio)-,2-(O-benzoyloxime)], ethanone, 1-[9-ethyl-6-(2-methyl benzoyl)-9H-carbazole-3-yl]- and 1-(O-acetyloxime). These may be used alone or two or more thereof may be used in combination.

### (2) Cationic Photo Polymeization Initiator

The cationic photo polymerization initiator is used for photo-polymerizing the cationic polymerization-type monomer with generating acid when it is exposed to light rays. The cationic photo polymerization initiator is not particularly limited, but well known cationic photo polymerization initiator can be employed. Practically, aromatic onium compound salts, such as, salts of sulfonic compounds, halide compounds, or iron arene complex can be used. The aromatic onium compound salts generate Lewis acid or Bronsted acid when they are exposed to light. The aromatic onium compound salts, such as, the compound salts comprising; B(C₆F₅)₄⁻, PF₆⁻, AsF₆⁻, SbF₆⁻ or CF₃SO₃⁻ and aromatic onium compounds such as, aromatic diazonium, aromatic ammonium, aromatic iodonium, aromatic sulfonium, or aromatic phosphonium can be used. Among these salts, aromatic iodonium salts and aromatic sulfonium salts are used in an embodiment. For example, sulfonium compound salts, such as (Ar¹)(Ar²)(Ar³)S⁺X⁻ type (Ar¹ and Ar² are, for example, 4-fluorophenyl group, Ar³ is -Ph-S-Ph-CO-Ph, X⁻=PF₆⁻) and iodonium compound salts, such as (Ar¹)(Ar²)I⁺X⁻ type (Ar¹ is, for example, 4-(2-propyl) phenyl group, and Ar² is, for example, p-toluoyl group, X⁻=PF₆⁻) are used in an embodiment. The sulfonium compounds generate sulfonic acid when they are exposed to light. As the sulfonium compounds, such as, PhCOCH₂SO₂Ph, (p-Tol) SO₂ OCH₂(2,6-DNP) (p-Tol is p-toluoyl group, 2,6-DNP is 2,6-di-nitro phenyl group) are employed. The halogen compounds generate halogenated hydrogen when exposed to light. As the halogen compounds, such as (4-Cl Ph)₂CHCCl₃, PhSO₂CBr₃ are used. The iron arene complexs generate Lewis acid when exposed to light. As the iron arene complex, such as [C₅H₅HFe(CO)₃]⁺PF₆⁻ are used.

### Cross-Linkable Agents

The conductive paste of the present invention is photo-curable because it contains the aforementioned cross-linkable agent (compound) and photo polymerization initiator. That is, the aforementioned cross-linkable compound is polymerized and cured by free radicals or acid generated by the photo polymerization initiator. It also has the effect of providing plasticity to the resin binder. Examples of this cross-linkable agent include ethylenically unsaturated compounds and cationic polymerizable compounds. A cross-linkable compound with a low molecular weight is desirable for providing suitable plasticity and fluidity to the conductive paste. On the other hand, a cross-linkable compound with a high molecular weight is desirable because it has an effect of stabilizing dispersion of the inorganic particles. The content of the cross-linkable compound in the conductive paste is 1.0 to 20 wt % in an embodiment or 5.0 to 15 wt % in another embodiment. From the standpoint of smooth photocuring and the fluidity and discharge performance of the conductive paste, the content is at least 1.0 wt % in an embodiment or at least 5.0 wt % in another embodiment, while for purposes of obtaining a sufficiently viscous conductive paste, as well as a satisfactory film thickness, an aspect value and a suitable resistance value of the formed electrode, the content is 20 wt % or less in an embodiment, or 15 wt % or less in another embodiment.

As the ethylenically unsaturated compound a cross-linkable compound having at least one polymerizable ethylene group can be used. Such a compound can cause the formation of the polymer, depending on the presence of free groups, and a chain-extending addition polymerization can take place. The monomer compound has a non-gas form, that is, it has a boiling point higher than 100° C. and can provide plasticity to the organic polymeric binder. Monomers that can be used either alone or in combination with other monomers include methyl-metacrylate, ethyl-metacrylate, n-buthyl-metacrylate, t-butyl (meth)acrylate, t-buthyl (meth)acrylate, 1,5-pentanediol di(meth)acrylate, (N,N-dimethyl aminoethyl(meth)acrylate, ethyle glycol di(meth)acrylate, 1,4-butanediol di(meth)acrylate, diethylene glycol di(meth)acrylate, hexamethylene glycol di(meth)acrylate, 1,3-propanediol di(meth)acrylate, decamethylene glycol di(meth)acrylate, 1,4-cyclohexanediol di(meth)acrylate, 2,2-dimethylolpropane di(meth)acrylate, glycerol di(meth)acrylate, tripropylene glycerol di(meth)acrylate, glycerol tri(meth)acrylate, trimethylolpropane tri(meth)acrylate, compounds disclosed in U.S. Pat. No. 3,380,381, 2,2-di(p-hydroxyphenyl)-propane di(meth)acrylate, pentaerythritol tetra(meth)acrylate, triethylene glycol diacrylate, polyoxyethyl-1,2-di-(p-hydroxyethyl)propane dimethacrylate, bisphenol A di-[3-(meth)acryloxy-2-hydroxypropyl)ether, bisphenol A di-[2-(meth)acryloxyethyle)ether, 1,4-butanediol di-(3-methacryloxy-2-hydroxypropyl)ether, triethylene glycol dimethacrylate, polyoxypropyl trimethyrol propane triacrylate, butylene glycol di(meth)acrylate, 1,2,4-butanediol tri(meth)acrylate, 2,2,4-trimethyl-1,3-pentanediol di(meth)acrylate, 1-phenylethylene-1,2-dimethacrylate, diallyl fumarate, styrene, 1,4-benzenediol dimethacrylate, 1,4-diisopropenyl benzene, and 1,3,5-triisopropenyl benzene (in this case, “(meth)acrylate” includes both “acrylate and methacrylate)”. The above polymerizable ethylenically unsaturated compound may be modified, for example, polyoxyethylated, or ethylated. Moreover, inorganic powder dispersal may be stabilized and the strength of a dried film may be enhanced by using an ethylenically unsaturated compound comprising an ethylenically unsaturated group added to an epoxy, polyether, polyester, polyurethane or other polymer chain. One such ethylenically unsaturated compound may be used alone, or a combination of two or more may be used.

The cationic polymerizable compound is also the cross-linkable agent used in the present invention, having at least one functional group, for example, an epoxy group, oxetane ring, vinyl ether or the like, that is polymerizable in the presence of an acid. This cross-linkable agent is non-gaseous with a boiling point above 100° C. in an embodiment. Polymerization of this cationic polymerizable compound may be initiated by moisture and other impurities in the air. This makes environmental control difficult when the paste is used for screen-printing. When it is used in a nozzle dispenser, on the other hand, it is easy to handle because it can be stored in a sealed container until immediately before the process.

Epoxy compounds that can be used as the cationic polymerizable compound are monomers or oligomers of compounds having epoxy groups, such as aromatic epoxy compounds, alicyclic epoxy compounds and aliphatic epoxy compounds. When an oligomer is used, it is non-gaseous with a boiling point above 100° C. in an embodiment. Examples of the aromatic epoxy compounds include di- or polyglycidyl ethers produced by reacting epichlorohydrin with a polyvalent phenol or alkylene oxide adduct thereof having at least one aromatic nucleus, and more specific examples include di- or polyglycidyl ethers of bisphenol A or its alkylene oxide adduct, di- or polyglycidyl ethers of hydrogenated bisphenol A or its alkylene oxide adduct, and Novolac epoxy resin and the like. Examples of the alicyclic epoxy compounds include cyclohexene oxide, cyclopentene oxide and the like. Examples of the aliphatic epoxy compounds include di- or polyglycidyl ethers of aliphatic polyvalent alcohols or their alkylene oxide adducts, and more specific examples include diglycidyl ethers of ethylene glycol, propylene glycol, 1,6-hexanediol and other alkylene glycols; polyglycidyl ethers of glycerin and other polyvalent alcohols; and diglycidyl ethers of polyethylene glycol, polypropylene glycol and other polyalkylene-oxyglycols and the like.

Compounds having oxetane rings can also be used as the cationic polymerizable compound, and these include monofunctional oxetane compounds and polyfunctional oxetane compounds. Examples of monofunctional oxetane compounds include 3-ethyl-3-hydroxymethyloxetane, 4-fluoro-[1-(3-ethyl-3-oxetanylmethoxy)methyl]benzene, 4-methoxy-[1-(3-ethyl-3-oxetanylmethoxy)methyl]benzene, isobutoxymethyl(3-ethyl-3-oxetanylmethyl)ether and other monofunctional oxetanes. Examples of polyfunctional oxetanes include 3,7-bis(3-oxetanyl)-5-oxa-nonane, 1,4-bis[(3-ethyl-3-oxetanylmethoxy)methyl]benzene, 1,2-bis[(3-ethyl-3-oxetanylmethoxy)methyl]ethane, 1,3-bis[(3-ethyl-3-oxetanylmethoxy)methyl]propane, ethylene glycol bis(3-ethyl-3-oxetanylmethyl)ether, dicyclopentenyl bis(3-ethyl-3-oxetanylmethyl)ether, triethylene glycol bis(3-ethyl-3-oxetanylmethyl)ether and the like.

Vinyl ether compounds can also be used as the cationic polymerizable compound, and these include monofunctional vinyl ethers and polyfunctional vinyl ethers. Examples of monofunctional vinyl ethers include methyl vinyl ether, ethyl vinyl ether, propyl vinyl ether, n-butyl vinyl ether, t-butyl vinyl ether and the like. Examples of polyfunctional vinyl ethers include ethylene glycol divinyl ether, diethylene glycol divinyl ether, polyethylene glycol divinyl ether, propylene glycol divinyl ether, butylene glycol divinyl ether and the like.

### Organic Solvent

The main purpose of using an organic solvent is so that the dispersion of the finely pulverized solid content of the aforementioned composition can be easily coated on wafers. Consequently, first of all, the organic solvent is able to disperse the solid content, i.e., the electrically conductive metal particles, the glass frit and any other solid additives, while maintaining the proper stability. Secondly, the rheological characteristics of the organic solvent provides the dispersion with a good coating characteristic.

In one embodiment, the organic solvent is used in the conductive paste to decrease the paste viscosity as well as to dissolve or disperse the each component (photo polymerization initiator, etc.) in the conductive paste. The content of the organic solvent in the conductive paste of the present invention is over 1.0 wt %, based on the total weight of the paste. When the content of the organic solvent is equal to or below 1.0 wt %, it will become very difficult to dissolve or disperse the components. in the conductive paste properly, and uniformly. As a result, to form fine and uniform lines on the wafer through a discharge slot of a nozzle dispenser will be difficult and forming electrodes with uniform and fine line width on the wafer will become difficult. On the other hand, too much content of the organic solvent in the paste can affect the photosensitivity of the electrodes in an adverse way. From that point of view, in one embodiment, the content of the organic solvent is less than 5.0 (wt %), based on the total weight of the conductive paste.

In addition, as for the above organic solvent composition, more than 90 wt % of the organic solvent component is organic solvent having a boiling point equal to or greater than 85° C. at 1 atmosphere pressure. When more than 90 wt % of the organic solvent component has a low boiling point (less than 85° C.), part of the organic solvent will be boiled away during the process and the composition of the paste, the viscosity of the paste and so on will be changed. The boiling point of the organic solvent is more than 90° C. in an embodiment, more than 100° C. in another embodiment. The organic solvent, having rather high boiling point (equal to or more than 85° C.) used in the present invention includes, for example, aliphatic alcohols, acetic esters, propionic esters, or the esters of the aforementioned alcohols; pine oil, α- or β-terpineol, or their mixture, or other terpinenes; ethylene glycol, di-ethylene glycol, ethylene glycol monobutyl ether, butyl Cellosolve acetate, or other esters of ethyelene glycols; butyl Carbitol, butyl Carbitol acetate, Carbitol acetate, or other carbitol esters; Texanol (2,2,4-trimethyl-1,3-pentanediol monoisobutyrate) and other appropriate solvents. These may be used alone, or two or more thereof may be used in combination. For example, the boiling point of Texanol is 255-260° C., the boiling point of butyl Carbitol acetate is 246.8 to 247° C., the boiling point of terpineol is 219° C., and the boiling point of di-ethylene glycol is 244° C.

### Additional Components

The conductive paste of the present invention may further comprise one or more additives, for example, polymeric binder, dispersants, stabilizers, plasticizers, antifoamers, wetting agents, thickeners and rheology modifiers. When the polymeric [resin] binder is included in the conductive paste of the present invention, the content of the polymeric binder in the conductive paste may be small in order to obtain a satisfactory photocuring speed. Specifically, the content is 1.0 wt % or less in an embodiment. Examples of the polymeric binder include copolymers or interpolymers prepared from (a) non-acidic comonomers containing C₁₋₁₀ alkyl acrylates, C₁₋₁₀ alkyl methacrylates, styrene, substituted styrene or combinations of these, and (b) acidic comonomers having ethylenically unsaturated carboxylic acid-containing parts. One of these may be used alone, or a combination of two or more may be used.

### Properties of Conductive Paste

### (1) Viscosity

The viscosity of the conductive paste in the present invention is 1 to 300 Pa·s in an embodiment. Specifically, a relatively low viscosity is about 1 to 100 Pa·s in an embodiment for increasing the discharge speed of the conductive paste, while 200 to 280 Pa·s is used in an embodiment for reducing the resistance value and increasing dispersibility in inorganic solvents. If the viscosity is less than 1 Pa·s, the inorganic particles are more likely to precipitate and separate, while if the viscosity exceeds 300 Pa·s, the nozzle unit is more likely to become clogged.

In the present invention, the viscosity of the conductive paste is a value obtained by measurement at 25° C., 10 rpm using a Brookfield HBT viscometer with a #14 spindle and a utility cup.

### (2) Application

As discussed in detail below, because the conductive paste of the present invention has the composition and physical properties described above, it can very efficiently and effectively form an electrode with a high aspect ratio when discharged from the nozzle unit of a nozzle dispenser. A nozzle dispenser as used herein is a discharge device with a nozzle unit, capable of coating, filling and sealing from the nozzle unit with a very small quantity of a high-viscosity paste or other high-viscosity fluid, and one example is the Image Master 350PC manufactured by Musashi Engineering.

### (3) Solid Components

When the conductive paste of the present invention is used in the method for producing a solar cell electrode in the second embodiment of the present invention described below, content of the solid components comprising the electrically conductive metal particles, the glass frit and any other solid additives of the conductive paste is 45 to 96 wt % or more in an embodiment, 70 to 90 wt % in another embodiment in order to more easily obtain fluidity of the conductive paste during discharge from the dispenser nozzle unit and a suitable viscosity after discharge. In order to balance the degree of photocuring with the resistance, the content of the monomer is 1.0 to 10 wt % in an embodiment as a percentage of the solids component of the conductive paste.

### (4) Paste Preparation

The conductive paste of the present invention may be prepared by mixing the various components described below in a three-roll mill. The conductive paste of the present invention forms an electrode pattern when it is discharged through a nozzle unit onto a wafer. A solar cell electrode with a high aspect ratio is provided in this way. In particular, as explained in detail below, this conductive paste is suitable for use in the method for producing a solar cell electrode of the second embodiment of the present invention.

### Production of Solar Cell Electrode Using Photo-Curable Conductive Paste

The method for producing a solar cell electrode of the second embodiment of the present invention is a method of production by discharging the photo-curable conductive paste of the first embodiment of the present invention from the nozzle unit of a nozzle dispenser, and more specifically, it comprises the steps (a) (b) and (c) of:

(a) providing the photo-curable conductive paste of the first embodiment of the present invention

(b) discharging the photo-curable conductive paste for solar cell electrode of the first embodiment of the present invention onto a wafer through a discharge slot of a nozzle unit of the dispenser while moving the nozzle unit relatively along the wafer in a specific direction to thereby form an uncured electrode pattern on the wafer; and

(c) curing the uncured electrode pattern by exposure to UV light, after or concurrently with step (a) of forming the electrode pattern on the wafer.

### Electrode Pattern Formation Step

This electrode pattern formation step is a step whereby a conductive paste is discharged onto a wafer through a discharge slot of a nozzle unit of the dispenser while this nozzle unit is moved relatively along the wafer in a direction to the surface of the wafer to thereby form an electrode pattern on the wafer.

The conductive paste adheres sequentially to the wafer by being discharged continuously without interruption in a direction opposite the direction of relative movement of the nozzle unit. The shape of the discharge slot is not particularly limited, and a variety of shapes including circular and rectangular are possible according to the properties of the conductive paste and the shape of the electrode being formed. The minimum inner diameter of the discharge slot is not particularly limited, but is 5 to 100 μm or more in an embodiment, 10 to 50 μm in another embodiment, considering the light-receiving area of the formed solar cell and the like. The number of discharge slots in the nozzle unit is not particularly limited, and there may be one discharge slot or multiple discharge slots. In particular, a nozzle unit having multiple discharge slots of the same shape and size is desirable for forming an electrode efficiently. The discharge slot (or nozzle unit) may also move relatively along the wafer in a specific direction at a specific angle to the wafer, or may move relatively along the wafer in a specific direction while maintaining a perpendicular position relative to the wafer. The conductive paste discharged from the discharge slot onto the wafer is the conductive paste for preparing a solar cell electrode of the first embodiment of the present invention. This has been explained above. The wafer may be a silicon wafer of a solar cell. The means by which the nozzle unit is moved relatively along the wafer in a specific direction is not particularly limited. For example, the nozzle unit may be fixed, while the wafer is mounted on an X-Y stage having an X-Y movement mechanism, and relative movement is accomplished by moving this movement mechanism so as to move the stage in the Y direction. The speed of the relative movement between the nozzle unit and the wafer is not particularly limited, but is 1 to 500 mm/s or more in an embodiment, 10 to 500 mm/s in another embodiment, considering the viscosity of the conductive paste used and the efficiency of discharge and coating and the like.

### UV Light Irradiation Step

The UV light irradiation step is a step of exposing the electrode pattern formed on the wafer to UV light. The irradiance level of the UV light is 10 to 1000 mJ/cm² in an embodiment in order to effectively form an electrode by efficient photocuring. In the UV light irradiation step, all of the (uncured) electrode patterns (or multiple patterns) can be formed first on the wafer in the electrode pattern formation step, after which these formed electrode patterns are exposed together to UV light. Alternatively, UV light irradiation can be performed successively for each electrode pattern formed on the wafer in the electrode pattern formation step. The latter is used in an embodiment from the standpoint of manufacturing an electrode pattern with a high aspect ratio. In this case in particular, it is desirable to perform UV light irradiation within 10 seconds after the electrode pattern is formed in order to obtain a suitable coating speed while preventing liquid dripping, although this also depends on the size of the electrode pattern. In this embodiment, the irradiance level of the UV light is about 100 to 1000 mJ/cm² in an embodiment when there is no firing step as explained below.

### Other Steps

Other steps include a firing step and the like. The method of firing is not particularly limited, but for example firing for about 1 to 15 minutes at a temperature of about 600 to 900° C. in a typical infrared firing furnace is desirable. As explained above, with the method for producing a solar cell electrode of the present invention it is possible to efficiently provide a solar cell electrode with a high aspect ratio by using the conductive paste of the present invention.

### Solar Cell Electrode

The solar cell electrode of the third embodiment of the present invention is manufactured by the solar cell electrode production method of the second embodiment of the present invention. Thus, it is formed efficiently as an electrode with a high aspect ratio and a small line width. An aspect ratio of 0.3 to 3.0 is desirable. The line width is 10 to 100 μm or more in an embodiment, 20 to 100 μm in another embodiment.

### Examples

The practical examples will be explained in further detail. The scope of the present invention, however is not limited in any way by these practical examples.

### (1) Formation of Solar Cell

A solar cell was formed as follows:

### (1-i) Photo-Curable Conductive Pastes Preparation

The conductive pastes of Examples 1, 2 and Comparative Examples 1, 2 and 3 were produced using the following materials.

### Materials

(a) Silver powder: The average particle size of the powder d₅₀=2.2 or 3.2 μm, spherical shape.
(b) Glass frits: Bismuth based glass frits

In addition to the above materials of (a) and (b), components shown in Table 1 were pre-mixed by THINKY mixer, then, repeatedly passed through a 3-roll mill for at progressively increasing pressures from 0 to 400 psi. The gap of the rolls was adjusted to 1 mil. The degree of dispersion was measured by fineness of grind (FOG). A typical FOG value is generally equal to or less than 20/10 for conductors. The 5 kinds of paste shown in Table 1 were prepared.

TABLE 1

| Paste composition | Ex. 1 | Ex. 2 | Co. Ex. 1 | Co. Ex. 2 | Co. Ex. 3 |
|---|---|---|---|---|---|
| Silver particle | (80.87 wt %) | (80.87 wt %) | (80.87 wt %) | (80.00 wt %) | (80.00 wt %) |
| d₅₀ (μm) | 2.20 μm | 2.20 μm | 2.20 μm | 3.20 μm | 3.20 μm |
| Bismuth-base glass | (3.32 wt %) | (3.32 wt %) | (3.32 wt %) | (2.00 wt %) | (2.00 wt %) |
| frit | | | | | |
| Zinc Oxide | (4.71 wt %) | (4.71 wt %) | (4.71 wt %) | — | — |
| Surfactant | (0.62 wt %) | (0.62 wt %) | (0.62 wt %) | — | — |
| Photo | *1 (1.28 wt %) | *1 (1.79 wt %) | — | *1 (1.00 wt %) | *1 (1.00 wt %) |
| polymerization | *2 (0.51 wt %) | | | *2 (0.50 wt %) | *2 (0.50 wt %) |
| initiator | | | | | |
| Cross-linkable | *3 (4.00 wt %) | *3 (4.00 wt %) | — | *4 (10.00 wt %) | *4 (9.2 wt %) |
| agent | | | | | |
| Stabilizer | *5 (0.10 wt %) | *5 (0.10 wt %) | — | *5 (0.05 wt %) | *5 (0.05 wt %) |
| Polymeric binder | *6 (0.32 wt %) | *6 (0.32 wt %) | *6 (0.86 wt %) | *7 (6.00 wt %) | *7 (6.00 wt %) |
| Organic solvent | Texanol (*10) | Texanol (*10) | Texanol (*10) | — | BCA/Texanol |
| | (4.27 wt %) | (4.27 wt %) | (9.62 wt %) | | (*10) (0.80 wt %) |
| Other additives | — | — | — | *8 (0.45 wt %) | *8 (0.45 wt %) |
| total (wt %) | 100.0 (wt %) | 100.0 (wt %) | 100.0 (wt %) | 100.0 (wt %) | 100.0 (wt %) |

*1: 1-methyl-1[4-(methylthio)phenyl]-2-morpholinopropanone-1-one
*2: 2,4-Diethylthioxantone
*3: Etoxylated pentaerythritol tetraacrylate (Sartomer Corporation, SR494 ®)
*4: Pentaerythritol tetraacrylate (Sartomer Corporation, SR295 ®)
*5: BHT(CAOR3) butylated hydroxytoluene lonol
*6: Ethylcellulose (EtCel ®, Dow Chemical Co.)
*7: Urethane acrylate (UA-510H, Kyoeisha Chemical Co., ltd.)
*8: Fatty acids, tall-oil, compds with n-tallow alkyltrimethylenediamines (DUOMEEN ® TDO) *
*9; The viscosity was mesured by utility cup with #14 spindle (Brookfield HBT, 10 rpm, at 25° C.).
(*10): Boiling point of Texanol ™: 255-260° C., Boiling point of BCA(=Butyl carbitol acetate): 246.8-247.

### (1-ii) Formation of Solar cell Electrodes

### Ex. 1-2 and Co. Ex. 2-3

1) As a dispenser (dispenser system machine), Image master 350PC (Musashi engineering Inc., manufactured) was provided. In the dispenser system machine, LED source which exposes ca. 10 mm diameter area was set up next to the nozzle unit as a UV light source. EXCURE-LE-1V (HOYA CANDEO OPTRONICS CORPORATION) was used as the UV light source. The smallest inner diameter of the slot of nozzle unit was 50 μm and the nozzle unit has only one discharging opening.

2) A 1.5×1.5 inches square silicon wafer was placed on the X-Y stage of the machine provided in 1). While each paste prepared in Ex. 1, Ex 2, Co. Ex. 2 and Co. Ex. 3 was being poured on the silicon wafer, the nozzle unit moved in X direction relative to the silicon wafer to form an electrode line pattern and then after that, the nozzle unit moved up in Y direction relative to the nozzle unit. 25 mm-long electrode patterns were formed on the silicon wafer. The scan speed of the nozzle unit relative to the wafer (X-direction) was 10 mm/sec. In the machine, the UV light source (LED source) was set up 50 mm away from the nozzle unit so that it could move behind the nozzle unit in the direction of the nozzle unit scanning. Five seconds after the formation of the electrode patterns, UV light was applied to the patterns for 1 second. With these steps, UV light cure was conducted. Irradiance level of the UV light (integrated value) was 200 to 250 m J/cm².

### (1-iii) Formation of Solar Cell Electrodes

### Co. Ex 1

Solar cell electrode of Co. Ex1 was formed as stated below.

On the surface of the front side-of a silicon wafer, conductive paste prepared in Co. Ex 1 in (1-i) was screen printed by using mask with 100 μm mesh opening and then dried. Right after printing, the screen-printed paste was dried at 100° C. With theses steps, sample of solar cell electrodes of Co. Ex1 was formed.

### (2) Properties, Evaluation and Results

(2-i) The width and thickness of electrodes formed in Ex. 1, Ex. 2 (1) (1-ii) and Co. Ex. 1(1-iii) were measured by laser microscope, respectively. The results of the evaluation are presented in Table 2.

(2-ii) In Co. Ex. 2 and Co. Ex. 3 in (1) (1-ii), properly-formed electrode line patterns were not provided at all. It was visually confirmed that the width and thickness of the electrode line patterns were obviously inhomogeneous over the entire line pattern. The width and thickness of these electrode line patterns were unmeasurable. For the sake of comparison, 3 power levels of UV light (100%, 50% and 25%) were applied to the conductive pastes (prepared in Co. Ex. 2 and Co. Ex. 3 in (1-ii)) poured on wafer, respectively. The results were similar regardless of UV power level.

TABLE 2

| Properties | Ex. 1 | Ex. 2 | Co. Ex.. 1 | Co. Ex. 2 | Co. Ex.. 3 |
|---|---|---|---|---|---|
| Width of electrode | 51 | 58 | 118 | — | — |
| line (μm) | | | | | |
| Thickness of electrode | 45 | 40 | 32 | — | — |
| line (μm) | | | | | |
| Aspect ratio | 0.88 | 0.69 | 0.27 | — | — |
| (Thickness/Width) | | | | | |

What is claimed is:

1. A photo-curable conductive paste for making a solar cell comprising:
electrically conductive metal particles;
glass frit;
a cross-linkable agent;
a photo polymerization initiator; and
organic solvent, wherein the content of the cross-linkable agent is 1.0 to 20.0 wt %, the content of the photo polymerization initiator is 0.2 to 15.0 wt %, and the content of the organic solvent is over 1.0 wt %, based on the weight of the paste, and wherein over 90 wt % of the organic solvent, based on the total weight of the organic solvent, has a boiling point at 85° C. or higher.

2. The photo-curable conductive paste of claim 1, wherein the viscosity of the paste at 10 rpm, 25° C. is 1.0 to 300 Pa·s.

3. The photo-curable conductive paste of claim 1, wherein the content of the glass frit is 0.5 wt % to 15.0 wt %, based on the total weight of the paste.

4. The photo-curable conductive paste of claim 1, wherein the content of the electrically conductive metal particles is 40 wt % to 95 wt %, based on the total weight of the paste.

5. The photo-curable conductive paste of claim 1, wherein the content of the organic solvent is less than 5.0 wt %, based on the total weight of the paste.

6. The photo-curable conductive paste of claim 1, further comprising polymeric binder, wherein the content of the polymeric binder is less than 1.0 wt %, based on the total weight of the paste.

7. The photo-curable conductive paste of claim 1, wherein the electrically conductive metal particles have spherical shape.

8. The photo-curable conductive paste of claim 1, wherein the content of solid components comprising the electrically conductive metal particles, the glass frit and any other solid additives is 45 to 96 wt %, based on the total weight of the paste.

9. The photo-curable conductive paste of claim 1, wherein the particle diameter (d₅₀) of the electrically conductive metal particles is 0.1 to 5.0 μm.

10. A method for producing a solar cell electrode by using a dispenser, comprising the steps:
(a) providing a paste for a solar cell electrode comprising:
electrically conductive metal particles:
glass frit;
a cross-linkable agent;
a photo polymerization initiator; and
organic solvent, wherein the content of the cross-linkable agent is 1.0 to 20.0 wt %, the content of the photo polymerization initiaor is 0.2 to 15.0 wt %, and the content of the organic solvent is over 1.0 wt %, based on the weight of the paste, and wherein over 90 wt % of the organic solvent, based on total weight of the organic solvent, has a boiling point at 85° C. or higher;
(b) discharging the paste onto a surface of a wafer through a discharge slot of a nozzle unit of a dispenser while moving the nozzle unit in a direction parallel to the surface of the wafer to thereby form an uncured electrode pattern on the surface of the wafer; and
(c) curing the uncured electrode pattern by exposing the uncured electrode pattern to UV light, after or concurrently with step (b) to form the electrode pattern on the wafer.

11. The method of claim 10, further comprising a step of: (d) firing the patterned and cured electrode after step (c).

12. The method of claim 10, wherein the minimum inner diameter of the discharge slot of the nozzle unit is 5 to 100 μm.

13. The method of claim 10, wherein the scan speed of the nozzle unit relative to the wafer while the conductive paste was being discharged onto the wafer was 1 to 500 mm/sec.

14. The method for producing a solar cell electrode according to claim 10, wherein the irradiance level of the UV light is 1 to 1000 mJ/cm².

15. A solar cell electrode produced by a method comprising the steps:
(a) providing a paste for a solar cell electrode comprising:
electrically conductive metal particles:
glass frit;
a cross-linkable agent;
a photo polymerization initiator; and
organic solvent, wherein the content of the cross-linkable agent is 1.0 to 20.0 wt %, the content of the photo polymerization initiator is 0.2 to 15.0 wt %, and the content of the organic solvent is over 1.0 wt %, based on the weight of the paste, and wherein over 90 wt % of the organic solvent, based on total weight of the organic solvent, has a boiling point at 85° C. or higher;
(b) discharging the paste onto a surface of a wafer through a discharge slot of a nozzle unit of a dispenser while moving the nozzle unit in a direction parallel to the surface of the wafer to thereby form an uncured electrode pattern on the surface of the wafer; and
(c) curing the uncured electrode pattern by exposing the uncured electrode pattern to UV light, after or concurrently with step (b) to form the electrode pattern on the wafer, wherein the aspect ratio of the electrode is 0.3 to 3.0.

16. The solar cell electrode of claim 15, wherein width of the electrode is 10 to 100 μm.
